(19) United States
(12) Patent Application Publication
(10) Pub. No.: US 2005/0258508 A1
(43) Pub. Date: Nov. 24, 2005

(54) Semiconductor device with inductors

(75) Inventor: Takehiko Sakamoto, Kanagawa (JP)

Correspondence Address: FOLEY AND LARDNER;SUITE 500, 3000 K STREET NW, WASHINGTON, DC, 20007, US

(73) Assignee: NEC Electronics Corporation

(21) Appl. No.: 11/111,786

(22) Filed: Apr. 22, 2005

(30) Foreign Application Priority Data
May 20, 2004 (JP) 2004-150441

(51) Int. Cl. H01L 29/00

(52) U.S. Cl. 257/531

(57) ABSTRACT

A semiconductor device includes a semiconductor substrate, and a multi-layered wiring arrangement formed on the semiconductor substrate and having insulating interlayers stacked in order thereon. A first inductor is formed on one of the insulating layers of the multi-layered wiring arrangement. A second inductor has a smaller size than the first inductor, and is formed on the same insulating interlayer as the first inductor, so that the second inductor is arranged inside of the first inductor.

### BACKGROUND OF THE INVENTION

1. Field of the Invention

The present invention relates to a semiconductor device having inductors formed therein.

2. Description of the Related Art

As well known, a semiconductor device includes a semiconductor substrate, such as a silicon substrate or the like, which has various electronic elements, such as transistors, resistors, capacitors and so on, formed therein. The semiconductor device further includes a multi-layered wiring arrangement formed on the semiconductor substrate, and the multi-layered wiring arrangement has insulating interlayers and wiring-pattern layers alternately stacked on each other such that a plurality of internal circuits are formed therein. Each of the internal circuits may have resistors, capacitors and so on formed in the multi-layered wiring arrangement, and is suitably connected to a part of the various electronic elements, formed in the silicon substrate, through the intermediary of via plugs.

The semiconductor device may comprise high frequency circuits including, for example, LC voltage controlled oscillators (VCO). In this case, each of the LCVCO's has at least one inductor formed in or on the multi-layered wiring arrangement. When each of the inductors is formed in or on the multi-layered wiring arrangement, it occupies a relatively large area in comparison with the other elements, such as a capacitor, a resistor or the like. For example, there may be a case where one inductor occupies an area of more than 40,000 μm².

When a plurality of inductors are formed in the semiconductor device, it is necessary to secure occupation areas corresponding to the number of inductors, as disclosed in, for example, JP-H06-077407, JP-A-2003-068862 and JP-A-3003-229485. Namely, a total of the occupation areas to be secured in the semiconductor device for the formation of the inductors becomes considerably large, resulting in an increase in production cost of the semiconductor device having the inductors.

### SUMMARY OF THE INVENTION

Therefore, an object of the present invention is to provide a semiconductor device having inductors formed therein, which is constituted such that a total of occupation areas to be secured in the semiconductor device for formation of the inductors can be considerably reduced.

In accordance with a first aspect of the present invention, there is provided a semiconductor device comprising, a semiconductor substrate, and a multi-layered wiring arrangement formed on the semiconductor substrate and having insulating interlayers stacked in order thereon. A first inductor is formed on one of the insulating layers of the multi-layered wiring arrangement. A second inductor has a smaller size than the first inductor, and is formed on the same insulating interlayer as the first inductor, so that the second inductor is arranged inside of the first inductor.

The insulating interlayer, on which the first and second inductors are formed, may be either an uppermost insulating interlayer of the multi-layered wiring arrangement or a middle uppermost insulating interlayer of the multi-layered wiring arrangement.

Preferably, the first and second inductors are concentrically arranged with respect to each other.

The semiconductor device may further comprise a third inductor having a smaller size than the second inductor and formed on the same insulating interlayer as the first and second inductors, so that the third inductor is arranged inside of the second inductor. In this case, preferably, the first, second and third inductors are concentrically arranged with respect to each other.

In accordance with a second aspect of the present invention, there is provided a semiconductor device comprising a semiconductor substrate, and a multi-layered wiring arrangement formed on the semiconductor substrate and having insulating interlayers stacked in order thereon. A composite inductor is formed and incorporated in two adjacent lower and upper insulating interlayers of the multi-layered wiring arrangement, and includes a first inductor section having at least one turn, and a second inductor section having at least one turn, the first and second inductor sections being connected to each other in series. The composite inductor further includes a conductive path extending from the connection between the first and second inductor sections.

Preferably, a part of the first inductor section is formed on the lower insulating interlayer, and the remaining part of the first inductor section is formed on the upper insulating interlayer such that both the parts of the first inductor section are connected to each other through via plugs formed in the upper insulating interlayer, to thereby avoid interference between the first and second inductor sections.

Preferably, a part of the second inductor section is formed on the lower insulating interlayer, and the remaining part of the second inductor section is formed on the upper insulating interlayer such that both the parts of the second inductor section are connected to each other through via plugs formed in the upper insulating interlayer, to thereby avoid interference between the first and second inductor sections.

The semiconductor device may further comprise a switching element provided between one of the first and second inductor sections and the conductive path extending from the connection between the first and second inductor sections, such that the composite inductor selectively functions as either a coil comprising the first and second inductors or a coil comprising only one of the first and second inductors.

### BRIEF DESCRIPTION OF THE DRAWINGS

The above object and other objects will be more clearly understood from the description set forth below, with reference to the accompanying drawings, wherein:

FIG. 1 is a partial vertical cross-sectional view of a first embodiment of a semiconductor device according to the present invention, taken along the I-I line of FIG. 2;

FIG. 2 is a partial horizontal cross-sectional view taken along the II-II line of FIG. 1;

FIG. 3 is a partial vertical cross-sectional view, similar to FIG. 1, showing a first modification of the first embodiment of the semiconductor device shown in FIGS. 1 and 2;

FIG. 4 is a partial horizontal cross-sectional view, similar to FIG. 2, showing a second modification of the first embodiment of the semiconductor device shown in FIGS. 1 and 2;

FIG. 5 is a partial vertical cross-sectional view of a second embodiment of the semiconductor device according to the present invention, taken along the V-V line of FIG. 2;

FIG. 6 is a partial plan view of the second embodiment of the semiconductor device of FIG. 5, from which a protective insulating layer is omitted;

FIG. 7 is a partial horizontal cross-sectional view taken along the VII-VII line of FIG. 5; and

FIG. 8 is a wiring diagram of an inductor included in the second embodiment of the semiconductor device according to the present invention.

### DESCRIPTION OF THE PREFERRED EMBODIMENTS

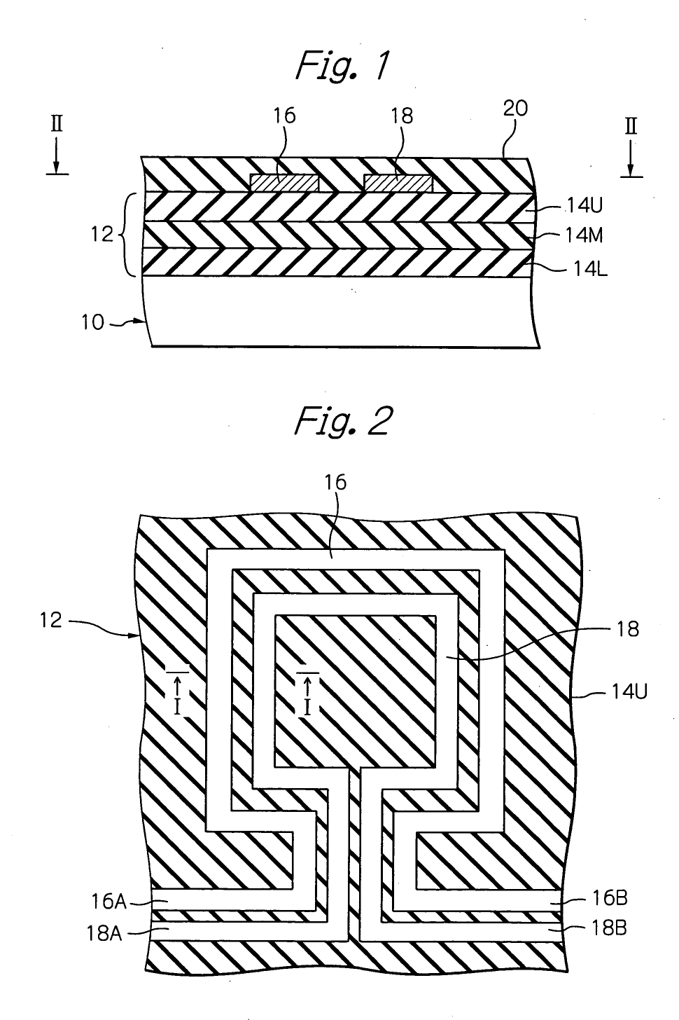

With reference to FIGS. 1 and 2, a first embodiment of a semiconductor device according to the present invention will now be explained below.

FIG. 1 shows a part of the first embodiment of the semiconductor device in a vertical cross-sectional view taken along the I-I line of FIG. 2, and FIG. 2 shows a part of the first embodiment of the semiconductor device in a horizontal cross-sectional view taken along the II-II line of FIG. 1.

As shown in FIG. 1, the semiconductor device includes a semiconductor substrate 10, which is derived from a monocrystalline silicon wafer, and various electronic elements, such as transistors, resistors, capacitors and so on, are formed in the semiconductor substrate 10. The formation of the various electronic elements is carried out by using well-known processes, such as a photolithography process, an etching process, a sputtering process and so on.

The semiconductor device also includes a multi-layered wiring arrangement 12 formed on the semiconductor substrate 10. In this embodiment, the multi-layered wiring arrangement 12 includes three insulating interlayers: a lowermost insulating interlayer 14L; a middle insulating interlayer 14M; and an uppermost insulating interlayer 14U stacked in order on the semiconductor substrate 10. Each of the insulating interlayers 14L, 14M and 14U may be formed of silicon dioxide, and the formation of the insulating interlayers 14L, 14M and 14U is carried out by using a suitable chemical vapor deposition (CVD) process.

Although not illustrated in FIG. 1, wiring patterns are suitably formed on each of the insulating interlayers 14L, 14M and 14U, and via plugs are suitably formed in each of the insulating interlayers 14L, 14M and 14U, so that internal circuits are formed in the multi-layered wiring arrangement 12 in conjunction with the various electronic elements which are formed in the semiconductor substrate 10. Note, each of the internal circuits may have electronic elements, such as resistors, capacitors and so on, formed in the multi-layered wiring arrangement 12.

In this embodiment, some of the internal circuits are formed as high frequency circuits including, for example, LC voltage controlled oscillators (VCO), and inductors 16 and 18 for defining the LCVCO's are formed on the multi-layered wiring arrangement 12. In FIGS. 1 and 2, only the two inductors 16 and 18 are representatively illustrated.

As shown in FIG. 2, each of the inductors 16 and 18 is defined as a rectangular coil having one turn, and they are concentrically arranged on the uppermost insulating interlayer 14U of the multi-layered wiring arrangement 12. Namely, the inductor 16 has a larger size than that of the inductor 18, and the inductor 18 is disposed in the inside of the inductor 16. In another aspect, the inductors 16 and 18 may be defined as respective outer and inner inductors having a common center.

The outer inductor 16 has conductive paths 16A and 16B which are integrally extended from the respective ends thereof, as shown in FIG. 2, and the conductive paths 16A and 16B are connected to a corresponding high frequency circuit including an LCVCO (not shown). Similarly, the inner inductor 18 has conductive paths 18A and 18B which are integrally extended from the respective ends thereof, and the conductive paths 18A and 18B are connected to a corresponding high frequency circuit including an LCVCO (not shown).

In this embodiment, the inductors 16 and 18 with the conductive paths 16A, 16B, 18A and 18B are composed of aluminum, and it is possible to carry out the formation of these elements by using a sputtering process, a photolithography process, an etching process and so on. In particular, an aluminum layer is formed on the uppermost insulating interlayer 14U of the multi-layered wiring arrangement 12 by using the sputtering process, and is then patterned by using the photolithography process and the etching process, resulting in the formation of the inductors 16 and 18 with the conductive paths 16A, 16B, 18A and 18B.

After the formation of the inductors 16 and 18 with the conductive paths 16A, 16B, 18A and 18B, a protective insulating layer 20 is formed on the uppermost insulating interlayer 14U of the multi-layer wiring arrangement 12 by using a suitable CVD process, resulting in the production of the semiconductor devices featuring the inductors 16 and 18 according to the present invention.

According to the above-mentioned first embodiment, since the inductors 16 and 18 are concentrically arranged on an area on the uppermost insulating interlayer 14U of the multi-layered wiring arrangement 12, it is possible to considerably reduce a total of occupation areas to be secured in the semiconductor device for formation of the inductors 16 and 18.

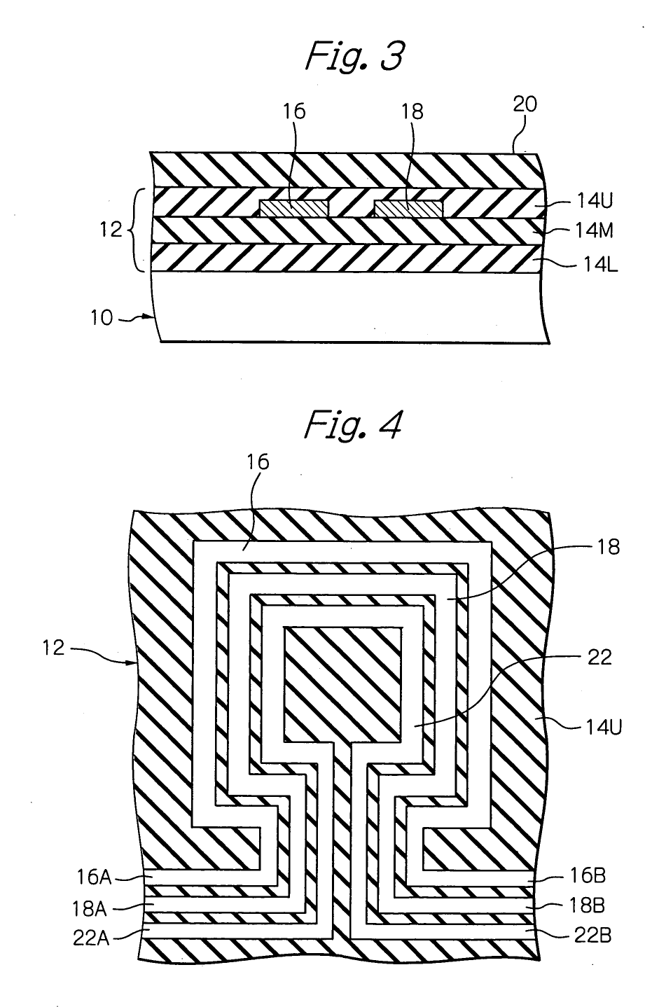

FIG. 3 shows a first modification of the above-mentioned first embodiment. Note, in FIG. 3 which is similar to FIG. 1, the features similar to those of FIG. 1 are represented by the same references.

In this first modification of the above-mentioned first embodiment, the inductors 16 and 18 are formed on the middle insulating interlayer 14M of the multi-layered wiring arrangement 12. Of course, the inductors 16 and 18 may be formed on the lowermost insulating interlayer 14L of the multi-layered wiring arrangement 12, if necessary.

FIG. 4 shows a second modification of the above-mentioned first embodiment. Note, in FIG. 4 which is similar to FIG. 2, the features similar to those of FIG. 1 are represented by the same references.

In this second modification of the above-mentioned first embodiment, a further inductor 22 is concentrically formed and arranged on the inside of the indicator 18. In this case, the respective inductors 16 and 18 and 22 may be defined as an outer inductor, an intermediate inductor and an inner inductor. Although not illustrated, similar to the inductors 16 and 18, the inductor 22 has conductive paths which are integrally extended from the respective ends thereof, and these conductive paths are connected to a corresponding high frequency circuit including an LCVCO (not shown).

According to the second modification of the above-mentioned first embodiment, the outer, intermediate and inner inductors 16, 18 and 22 are concentrically arranged on an area on the uppermost insulating interlayer 14U of the multi-layered wiring arrangement 12, and thus it is possible to further reduce a total of occupation areas to be secured in the semiconductor device for formation of the inductors 16, 18 and 22.

In the above-mentioned embodiments, although the inductors (16, 18, 22) with the conductive paths (16A, 16B, 18A, 18B) are composed of aluminum, they may be formed of copper by using a damascene process. In this case, it is necessary to cover the copper elements with a suitable material, such as silicon nitride, so that copper is prevented from being diffused from both the copper elements into the insulating interlayers (14M, 14U) composed of silicon dioxide.

Also, in the above-mentioned embodiments, although each of the inductors 16 and 18 has a rectangular shape, it may be defined as another polygonal inductor, such as a pentagonal inductor, a hexagonal inductor or the like. On the other hand, each of the inductors 16 and 18 may be defined as a circular inductor.

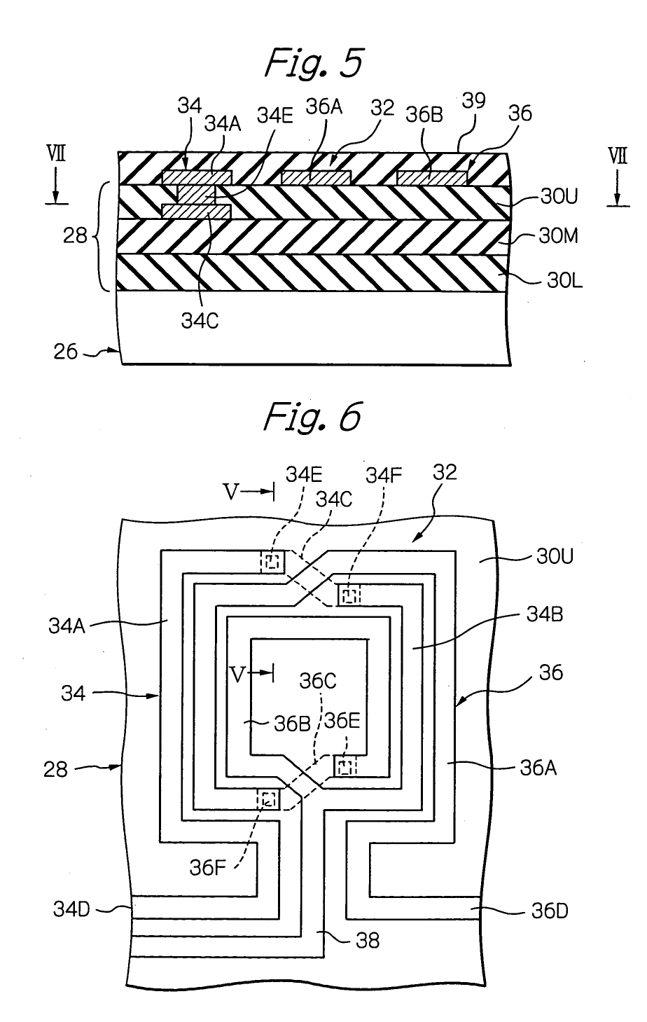

With reference to FIGS. 5 to 8, a second embodiment of the semiconductor device according to the present invention will now be explained below.

Similar to the above-mentioned first embodiment, in the second embodiment, as shown in FIG. 5, the semiconductor device includes a semiconductor substrate 26, which is derived from a monocrystalline silicon wafer, and various electronic elements, such as transistors, resistors, capacitors and so on, are formed in the semiconductor substrate 26. The formation of the various electronic elements is carried out by using well-known processes, such as a photolithography process, an etching process, a sputtering process and so on.

The semiconductor device also includes a multi-layered wiring arrangement 28 formed on the semiconductor substrate 26. Similar to the above-mentioned first embodiment, the multi-layered wiring arrangement 28 includes three insulating interlayers: a lowermost insulating interlayer 30L; a middle insulating interlayer 30M; and an uppermost insulating interlayer 30U stacked in order on the semiconductor substrate 26. Each of the insulating interlayers 30L, 30M and 30U may be formed of silicon dioxide, and the formation of the insulating interlayers 30L, 30M and 30U is carried out by using a suitable CVD process.

Although not illustrated in FIG. 5, wiring patterns are suitably formed on each of the insulating interlayers 30L, 30M and 30U, and via plugs are suitably formed in each of the insulating interlayers 30L, 30M and 30U, so that internal circuits are formed in the multi-layered wiring arrangement 28 in conjunction with the various electronic elements which are formed in the semiconductor substrate 26. Note, each of the internal circuits may have electronic elements, such as resistors, capacitors and so on, formed in the multi-layered wiring arrangement 26.

Similar to the above-mentioned first embodiment, in this second embodiment, some of the internal circuits are formed as high frequency circuits including, for example, LC voltage controlled oscillators (VCO), and composite inductors for defining the LCVCO's are formed on the multi-layered wiring arrangement 26. In FIGS. 5 and 6, only one composite inductor, generally indicated by reference 32, is representatively illustrated.

In the second embodiment, the composite inductor 32 includes a first inductor section 34 defined as a rectangular coil having one turn, and a second inductor section 36 defined as a rectangular coil having two turns.

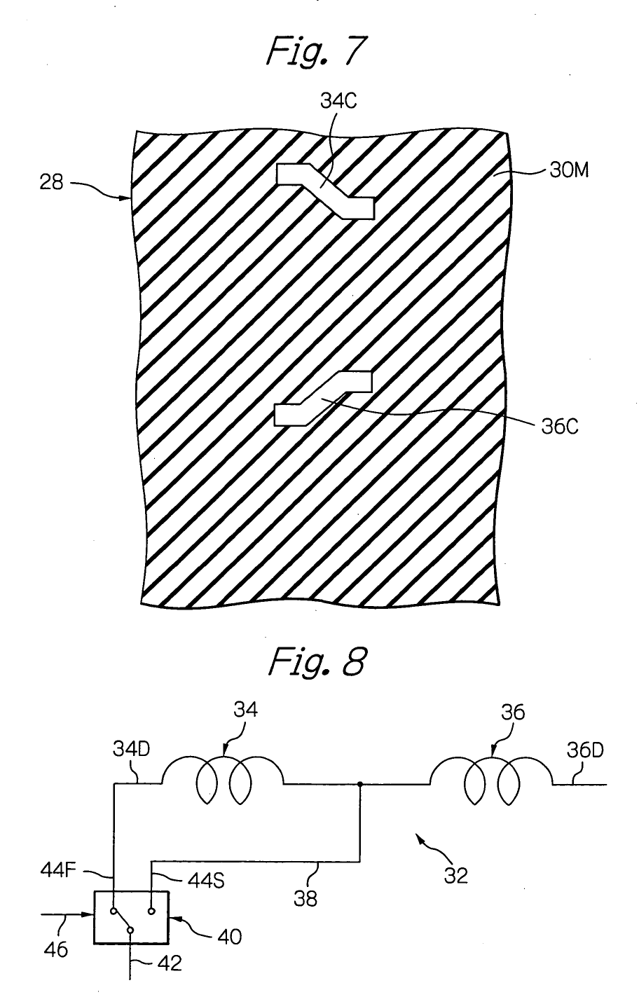

In particular, the first inductor section 34 has a first coil portion 34A and a second coil portion 34B which are formed on the upper insulating interlayer 30U of the multi-layered wiring arrangement 28, as shown in FIG. 6, and a third coil portion 34C which is formed on the middle insulating interlayer 30M, as best shown in FIG. 7. The first inductor section 34 has a conductive path 34D which is formed on the uppermost insulating interlayer 30U, and which is integrally connected to one end of the first coil portion 34A. The other end of the first coil portion 34A is connected to one end of the third coil portion 34C through the intermediary of a via plug 34E formed in the uppermost insulating interlayer 30U, and the other end of the third coil portion 34C is connected to one end of the second coil portion 34B through the intermediary of a via plug 34F formed in the uppermost insulating interlayer 30U. Namely, as is apparent from FIG. 6, the one turn of the first inductor 34 is defined by the first, second and third coil portions 34A, 34B and 34C connected to each other by the via plugs 34E and 34F.

On the other hand, the second inductor section 36 has a first coil portion 36A and a second coil portion 36B which are formed on the upper insulating interlayer 30U of the multi-layered wiring arrangement 28, as shown in FIG. 6, and a third coil portion 36C which is formed on the middle insulating interlayer 30M, as best shown in FIG. 7. The second inductor section 36 has a conductive path 36D which is formed on the uppermost insulating interlayer 30U, and which is integrally connected to one end of the first coil portion 36A. The second inductor section 36 has a conductive path 36D which is formed on the uppermost insulating interlayer 30U, and which is integrally connected to one end of the first coil portion 36A. The other end of the first coil portion 36A is connected to one end of the third coil portion 34C through the intermediary of a via plug 36E formed in the uppermost insulating interlayer 30U, and the other end of the third coil portion 36C is connected to one end of the second coil portion 36B through the intermediary of a via plug 36F formed in the uppermost insulating interlayer 30U. Namely, as is apparent from FIG. 6, the two turns of the first inductor 36 are defined by the first, second and third coil portions 36A, 36B and 36C connected to each other by the via plugs 36E and 36F.

As shown in FIG. 6, the other end of the second coil portion 34B and the other end of the second coil portion 36B are integrally connected to each other, and a conductive path 38 is integrally extended from both of the connected ends of the second coil portions 34B and 36B.

As is apparent from FIGS. 5, 6 and 7, by forming and incorporating the coil portions (34A, 34B and 34C; and 36A, 36B and 36C) in the two adjacent insulating interlayers 30M and 30U of the multi-layered arrangement 28, it is possible to establish the composite inductor 32 so that the first and second inductors 34 and 36 do not interfere with each other.

In particular, a part of the first inductor section 34 is formed as the third coil portion 34C on the middle insulating interlayer 30M, and the remaining part of the first inductor section 34 is formed as the first and second coil portions 34A and 34B on the uppermost insulating interlayer 30U so that both the parts of the first inductor section 34 are connected to each other through the intermediary of the via plugs 34E and 34F, to thereby avoid the interference between first and second inductor sections 34 and 36.

Similarly, a part of the second inductor section 36 is formed as the third coil portion 36C on the middle insulating interlayer 30M, and the remaining part of the second inductor section 36 is formed as the first and second coil portions 36A and 36B on the uppermost insulating interlayer 30U so that both the parts of the second inductor section 36 are connected to each other through the intermediary of the via plugs 36E and 36F, to thereby avoid the interference between first and second inductor sections 34 and 36.

Similar to the above-mentioned first embodiment, the composite inductor 32 with the conductive paths 34D, 36D and 38 may be composed of aluminum, and it is possible to carry out the formation of these elements by using a sputtering process, a photolithography process, an etching process, a CVD process and so on.

In particular, an aluminum layer is formed on the middle insulating interlayer 30M of the multi-layered wiring arrangement 28 by using the sputtering process, and is then patterned by using the photolithography process and the etching process, resulting in the formation of the third coil portions 34C and 36C. Then, the formation of the uppermost insulating interlayer 30M is carried out by using the CVD process, and the formation of the via plugs 34E, 34F, 36E and 36F is carried out by using the photolithography process, the etching process and the sputtering process. Thereafter, an aluminum layer is formed on the uppermost insulating interlayer 30U by using the sputtering process, and is then patterned by using the photolithography process and the etching process, resulting in the formation of the coil portions 34A, 34B, 36A and 36B with the conductive paths 34D, 36D and 38.

After the formation of the composite inductor 32 with the conductive paths 34D, 36D and 38, a protective insulating layer 39 is formed on the uppermost insulating interlayer 30U of the multi-layer wiring arrangement 28 by using a suitable CVD process, resulting in the production of the semiconductor devices featuring the composite induction 32 according to the present invention.

With reference to FIG. 8, the composite inductor 32 is illustrated as a wiring diagram. As shown in this wiring diagram, in the second embodiment, the semiconductor device is provided with a switch element 40 which may be formed as a complementary metal oxide semiconductor (CMOS) switch element. Note, although not illustrated in FIG. 5, the SMOS switch element 40 is formed in the semiconductor substrate 26.

As shown in FIG. 8, the CMOS switch element 40 has an input terminal 42, a first output terminal 44F, a second output terminal 44S, and a control signal input terminal 46. The input terminal 42 is suitably connected to a corresponding high frequency circuit including an LCVCO (not shown). The conductive path 34D is connected to the first output terminal 44F, and the conductive path 38 is connected to the second output terminal 44F. The conductive path 36D and the control signal input terminal 46 are suitably connected to the high frequency circuit.

In the CMOS switch element 40 shown in FIG. 8, the high frequency circuit outputs a switching control signal to the control signal input terminal 46. For example, when the switching control signal is a high level, the input terminal 42 is connected to the first output terminal 44F, as shown in FIG. 8, so that the composite inductor 32 functions as the coil having the three turns, because the first and second inductor sections 34 and 36 are connected to each other in series.

On the other hand, when the switching control signal is changed from the high level to a low level, the input terminal 42 is switched from the first output terminal 44F to the second output terminal 44S, to thereby establish a connection between the input output terminal 42 and the second output terminal 44S. Thus, the first indicator section 34 of the composite inductor 32 is disabled, and only the second inductor section 36 of the composite inductor 32 is enabled. Namely, the composite inductor 32 functions as a coil having the two turns.

In short, in the second embodiment, the composite inductor 32 can selectively function as either a coil having the three turns or a coil having the two turns. In other words, it is unnecessary to secure two occupation areas for forming an inductor having three turns and an inductor having two turns in the semiconductor device. Thus, it is possible to considerably reduce a total of occupation areas to be secured in the semiconductor device for formation of the inductors.

Similar to the above-mentioned first embodiment, in the second embodiment, the coil portions 34A, 34B, 34C, 36A, 36B and 36C, the conductive paths 24D, 35D and 38, and the via plugs 34E, 34F, 36E and 36F may be formed of copper by using a damascene process. Of course, in this case, it is necessary to cover the copper elements with a suitable material, such as silicon nitride, so that copper is prevented from being diffused from both the copper elements into the insulating interlayers (30M, 30U) composed of silicon dioxide. Also, in the second embodiment, by using a dual damascene process, it is possible to simultaneously carry out the formation of the coil portions 34A, 34B, 36A and 36B and the formation of the copper via plugs 34E, 34F, 36E and 36F.

In the above-mentioned second embodiment, although the first inductor section 34 is defined as a coil having one turn, it may be defined as a coil having more than one turn, if necessary. Also, although the second inductor section 36 is defined as a coil having two turns, it may be defined as either a coil having one turn or a coil having more than two turns.

Also, in the above-mentioned second embodiment, although the CMOS switch element is provided between the conductive path 34D of the first inductor section 34 and the conductive path 38, it may be provided between the conductive path 36D of the second inductor section 36 and the conductive path 38.

Finally, it will be understood by those skilled in the art that the foregoing description is of preferred embodiments of the device, and that various changes and modifications may be made to the present invention without departing from the spirit and scope thereof.

1. A semiconductor device comprising:
a semiconductor substrate;
a multi-layered wiring arrangement formed on said semiconductor substrate and having insulating interlayers stacked in order thereon;
a first inductor formed on one of the insulating layers of said multi-layered wiring arrangement; and
a second inductor having a smaller size than said first inductor and formed on the same insulating interlayer as said first inductor, so that said second inductor is arranged inside of said first inductor.

2. The semiconductor device as set forth in claim 1, wherein the insulating interlayer on which said first and second inductors are formed, is an uppermost insulating interlayer of said multi-layered wiring arrangement.

3. The semiconductor device as set forth in claim 1, wherein the insulating interlayer on which said first and second inductors are formed, is a middle uppermost insulating interlayer of said multi-layered wiring arrangement.

4. The semiconductor device as set forth in claim 1, wherein said first and second inductors are concentrically arranged with respect to each other.

5. The semiconductor device as set forth in claim 1, further comprising a third inductor having a smaller size than said second inductor and formed on the same insulating interlayer as said first and second inductors, so that said third inductor is arranged inside of said second inductor.

6. The semiconductor device as set forth in claim 5, wherein said first, second and third inductors are concentrically arranged with respect to each other.

7. A semiconductor device comprising:
a semiconductor substrate;
a multi-layered wiring arrangement formed on said semiconductor substrate and having insulating interlayers stacked in order thereon; and
a composite inductor formed and incorporated in two adjacent lower and upper insulating interlayers of said multi-layered wiring arrangement,
wherein said composite inductor includes a first inductor section having at least one turn, and a second inductor section having at least one turn, said first and second inductor sections being connected to each other in series, and wherein said composite inductor further includes a conductive path extending from the connection between said first and second inductor sections.

8. The semiconductor device as set forth in claim 7, wherein a part of said first inductor section is formed on said lower insulating interlayer, and a remaining part of said first inductor section is formed on said upper insulating interlayer such that both the parts of said first inductor section are connected to each other through via plugs formed in said upper insulating interlayer, to thereby avoid interference between said first and second inductor sections.

9. The semiconductor device as set forth in claim 7, wherein a part of said second inductor section is formed on said lower insulating interlayer, and a remaining part of said second inductor section is formed on said upper insulating interlayer such that both the parts of said second inductor section are connected to each other through via plugs formed in said upper insulating interlayer, to thereby avoid interference between said first and second inductor sections.

10. The semiconductor device as set forth in claim 7, further comprising a switching element provided between one of said first and second inductor sections and the conductive path extending from the connection between said first and second inductor sections, such that the composite inductor selectively functions as either a coil comprising said first and second inductors or a coil comprising only one of said first and second inductors.
